(19) United States
(12) Patent Application Publication
(10) Pub. No.: US 2019/0146315 A1
(43) Pub. Date: May 16, 2019

(54) Heat Dissipation Module

(71) Applicant: Coretronic Corporation, Hsin-Chu (TW)

(72) Inventors: Tsung-Ching Lin, Hsin-Chu (TW); Jhih-Hao Chen, Hsin-Chu (TW); Shih-Yao Li, Hsin-Chu (TW); Po-Sheng Huang, Hsin-Chu (TW)

(21) Appl. No.: 16/186,338

(22) Filed: Nov. 9, 2018

(30) Foreign Application Priority Data
Nov. 15, 2017 (CN) 201711129248.8

(51) Int. Cl. G03B 21/16; F28D 15/02; H05K 7/20

(52) U.S. Cl. CPC G03B 21/16; H05K 7/20336; H05K 7/20136; F28D 15/02

(57) ABSTRACT

The invention discloses a heat dissipation module, comprising a plurality of heat dissipation fins and a plurality of heat pipes. The heat dissipation fins are spaced apart from each other and disposed side by side. A gas flow passageway is formed between two adjacent heat dissipation fins. The gas flow passageway has an inlet end and an outlet end. The outlet end is opposite to the inlet end. Each of the heat pipes is threaded through the heat dissipation fins along an extension direction. In a cross section of each of the heat pipes perpendicular to the extension direction, a maximum length in a first longitudinal direction is L1, a maximum length in a second longitudinal direction is L2, and L1>L2. The invention further provides a heat dissipation module for a projector. The heat dissipation module of the invention is used for enhancing the efficiency of heat dissipation.

### CROSS-REFERENCE TO RELATED APPLICATION

THIS APPLICATION CLAIMS THE PRIORITY BENEFIT OF CHINA APPLICATION (CN201711129248.8 FILED ON 2017 Nov. 15). THE ENTIRETY OF THE ABOVE-MENTIONED PATENT APPLICATION IS HEREBY INCORPORATED BY REFERENCE HEREIN AND MADE A PART OF THIS SPECIFICATION.

### FIELD OF THE INVENTION

The invention relates to a heat dissipation module, and more particularly to a heat dissipation module that can be applied to a projector.

### BACKGROUND OF THE INVENTION

Most electronic products nowadays pursue high performance and small size. In order to improve performance, elements in the electronic product tend to generate more thermal energy to derive a heat dissipation problem. In addition, the reduced size of the electronic product will make the design of a heat dissipation mechanism difficult and make the heat dissipation problem more difficult to be overcome.

In order to achieve a better effect of heat dissipation, the heat dissipation mechanism of some electronic products utilizes heat pipes with high thermal conductivity to conduct the thermal energy to heat dissipation fins. At present, although the heat pipes have been widely used, as far as heat dissipation issues are concerned, how to allow the heat dissipation mechanism, which utilizes the heat pipes, to have better efficiency of heat dissipation is still one of the focuses of research.

The information disclosed in this “BACKGROUND OF THE INVENTION” section is only for enhancement understanding of the background of the invention and therefore it may contain information that does not form the prior art that is already known to a person of ordinary skill in the art. Furthermore, the information disclosed in this “BACKGROUND OF THE INVENTION” section does not mean that one or more problems to be solved by one or more embodiments of the invention were acknowledged by a person of ordinary skill in the art.

### SUMMARY OF THE INVENTION

The invention provides a heat dissipation module, so as to enhance the efficiency of heat dissipation.

The invention provides a heat dissipation module, used for a projector, so as to enhance the efficiency of heat dissipation.

Other objectives and advantages of the invention can be further understood from the technical features disclosed in the invention.

In order to achieve one or a portion of or all of the objectives or other objectives, an embodiment of the invention provides a heat dissipation module, comprising a plurality of heat dissipation fins and a plurality of heat pipes. The heat dissipation fins are spaced apart from each other and disposed side by side. A gas flow passageway is formed between two adjacent heat dissipation fins. The gas flow passageway has an inlet end and an outlet end. The outlet end is opposite to the inlet end. Each of the heat pipes is threaded through the heat dissipation fins along an extension direction. The heat pipes are spaced apart from each other. In a cross section of each of the heat pipes perpendicular to the extension direction, a maximum length in a first longitudinal direction of each of the heat pipes is L1, and a maximum length in a second longitudinal direction of each of the heat pipes is L2. The first longitudinal direction is from the inlet end toward the outlet end. The second longitudinal direction is perpendicular to the first longitudinal direction, and L1>L2.

In order to achieve one or a portion of or all of the objectives or other objectives, an embodiment of the invention provides a heat dissipation module, used for a projector. The projector includes a housing and a heat source. The housing has an air inlet. The heat source and the heat dissipation module are disposed in the housing. The heat dissipation module is located between the air inlet and the heat source. The heat dissipation module includes a plurality of heat dissipation fins and a plurality of heat pipes. The heat dissipation fins are spaced apart from each other and disposed side by side. A gas flow passageway is formed between two adjacent heat dissipation fins. The gas flow passageway has an inlet end and an outlet end. The outlet end is opposite to the inlet end. Each of the heat pipes is threaded through the heat dissipation fins along an extension direction. The heat pipes are spaced apart from each other. In a cross section of each of the heat pipes perpendicular to the extension direction, a maximum length in a first longitudinal direction of each of the heat pipes is L1, and a maximum length in a second longitudinal direction of each of the heat pipes is L2. The first longitudinal direction is from the inlet end toward the outlet end. The second longitudinal direction is perpendicular to the first longitudinal direction, and L1>L2.

In the heat dissipation module of the embodiment of the invention, the maximum length L1 in the first longitudinal direction is greater than the maximum length L2 in the second longitudinal direction in the cross section of the heat pipe perpendicular to the extension direction. When applied to a projector or other electronic device, airflow can be configured to flow through the heat pipe along the first longitudinal direction, so as to reduce a flow resistance to the airflow caused by the heat pipe, and to increase a flow amount of the airflow passing through the heat dissipation fins. The temperature uniformity of the heat dissipation fins in a direction parallel to the direction of the airflow, and air-side heat conductivity can further be enhanced. Therefore, the efficiency of heat dissipation can be enhanced.

Other objectives, features and advantages of the invention will be further understood from the further technological features disclosed by the embodiments of the invention wherein there are shown and described preferred embodiments of this invention, simply by way of illustration of modes best suited to carry out the invention.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic perspective view of a heat dissipation module of an embodiment of the invention;

FIG. 2 is a schematic cross-sectional view of the heat dissipation module of FIG. 1, perpendicular to an extension direction of heat pipes;

FIG. 3 is a schematic view of the heat dissipation module of FIG. 1 applied to an electronic product;

FIG. 4 is a schematic cross-sectional view of a heat dissipation module of another embodiment of the invention, perpendicular to an extension direction of heat pipes;

FIG. 5 is a schematic cross-sectional view of a heat dissipation module of another embodiment of the invention, perpendicular to an extension direction of heat pipes;

FIG. 6 is a schematic cross-sectional view of a heat dissipation module of another embodiment of the invention, perpendicular to an extension direction of heat pipes;

FIG. 7-1 is a schematic cross-sectional view of a heat dissipation module of another embodiment of the invention, perpendicular to an extension direction of heat pipes;

FIG. 7-2 is a schematic cross-sectional view of a heat dissipation module of another embodiment of the invention, perpendicular to an extension direction of heat pipes;

FIG. 8 is a schematic view of a heat dissipation module applied to an electronic product in accordance with another embodiment of the invention; and

FIG. 9 is a schematic view of a heat dissipation module applied to an electronic product in accordance with another embodiment of the invention.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

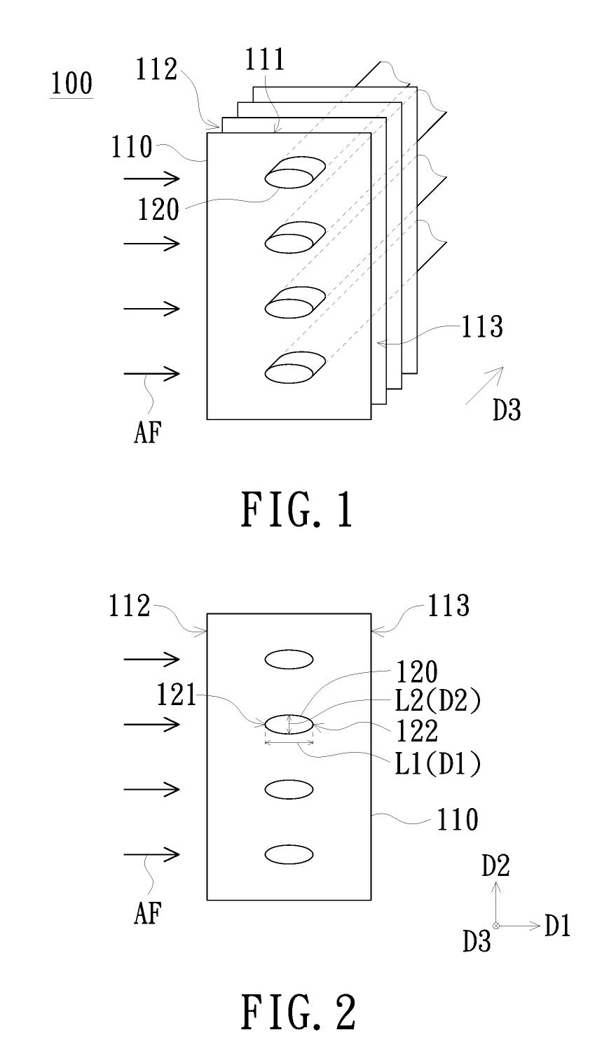

FIG. 1 is a schematic perspective view of a heat dissipation module of an embodiment of the invention. FIG. 2 is a schematic cross-sectional view of the heat dissipation module of FIG. 1, perpendicular to an extension direction of heat pipes. Please refer to FIG. 1 and FIG. 2. The heat dissipation module 100 of the embodiment includes a plurality of heat dissipation fins 110 and a plurality of heat pipes 120. The heat dissipation fins 110 are spaced apart from each other and disposed side by side. A gas flow passageway 111 is formed between two adjacent heat dissipation fins 110. The gas flow passageway 111 has an inlet end 112 and an outlet end 113. The outlet end 113 is opposite to the inlet end 112. In addition, the gas flow passageway 111 has, at the same time, an upper inlet end and a lower inlet end (not shown) relative to two sides of the inlet end 112. An airflow AF can flow from the inlet end 112 to the outlet end 113 through the gas flow passageway 111. Each of the heat pipes 120 is threaded through the heat dissipation fins 110 along an extension direction D3. The heat pipes 120 are spaced apart from each other.

As shown in FIG. 2, in a cross section of each of the heat pipes 120 perpendicular to the extension direction D3, a maximum length of each of the heat pipes 120 in a first longitudinal direction D1 is L1, and a maximum length of each of the heat pipes 120 in a second longitudinal direction D2 is L2. The first longitudinal direction D1 is from the inlet end 112 toward the outlet end 113. The second longitudinal direction D2 is perpendicular to the first longitudinal direction D1, and L1>L2. In an embodiment, 1>L2/L1>0.05. Because L1>L2, a cross section of the heat pipe 120 perpendicular to the extension direction D3 is in an oblate shape, for example, an oval. The first longitudinal direction D1 approximately matches a flow direction of the airflow AF in the gas flow passageway 111. In the embodiment, the first longitudinal direction D1 of each of the heat pipes 120 is, for example, perpendicular to the inlet end 112 of the gas flow passageway 111. A cross section of each of the heat pipes 120 perpendicular to the extension direction D3 is, for example, oval. The heat pipes 120 are, for example, arranged in a row. In other embodiments, a cross section of the heat pipe 120 perpendicular to the extension direction D3 is in a crescent shape. A maximum length in the first longitudinal direction D1 is greater than a maximum length in the second longitudinal direction D2.

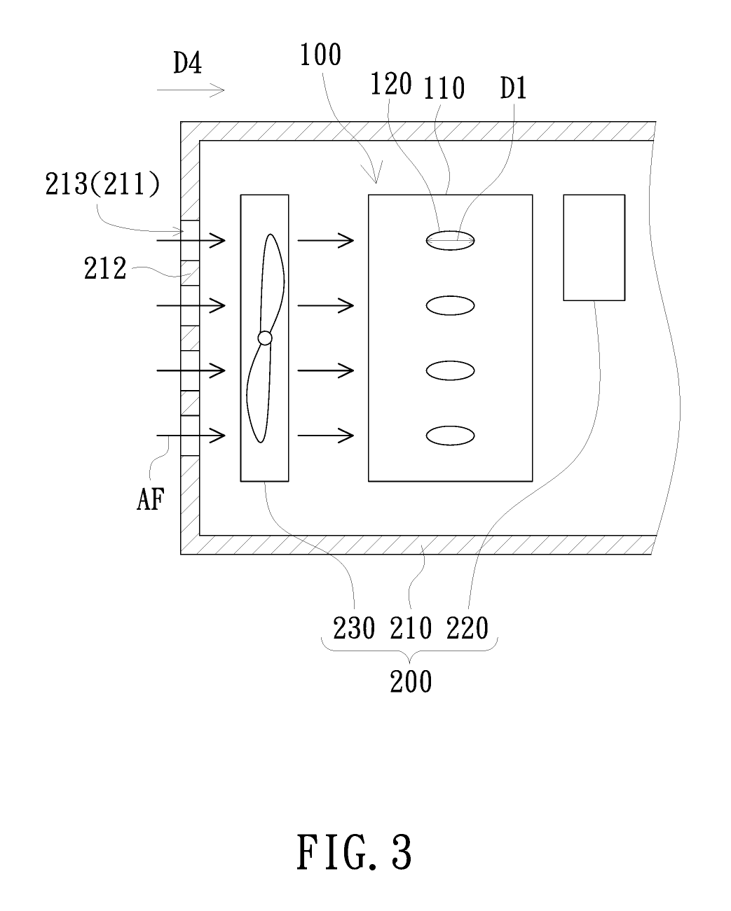

FIG. 3 is a schematic view of the heat dissipation module of FIG. 1 applied to an electronic product. Please refer to FIG. 1 and FIG. 3. The electronic product 200 may be a projector, but not limited thereto. The electronic product 200 includes a housing 210 and a heat source 220. The housing 210 has an air inlet 211. The heat source 220 and the heat dissipation module 100 are disposed in the housing 210. The heat dissipation module 100 is located between the air inlet 211 and the heat source 220. The heat source 220 may be an element that generates a large amount of thermal energy in the electronic product 200. Taking the electronic product 200 being a projector as an example, the heat source 220 is, for example, a light source or a light valve (DMD or LCD panel). In addition, the air inlet 211 of the housing 210 may be provided with a grid structure 212 to form a plurality of air intake passageways 213. A flow direction of the airflow AF before entering the gas flow passageway 111 of the heat dissipation module 100 is affected by a diversion direction D4 of the air intake passageway 213. The first longitudinal direction D1 of the heat pipe 120 of the embodiment is, for example, disposed parallel to the diversion direction D4 of the air intake passageway 213, so that the airflow AF can flow through the heat pipe 120 approximately along the first longitudinal direction D1 in the gas flow passageway 111 of the heat dissipation module 100.

The electronic product 200 may further include a fan 230. The fan 230 is disposed between the air inlet 211 and the heat dissipation module 100, so as to guide the cooling air to enter the electronic product 200 from the outside of the electronic product 200 to generate the airflow AF. In other embodiments, the fan 230 may also be disposed between the heat dissipation module 100 and the heat source 220, or at a side of the heat source 220 away from the heat dissipation module 100.

Different from the circular heat pipes utilized in the prior art, a cross section of the heat pipe 120 of the embodiment of the invention perpendicular to the extension direction D3 is in an oblate shape. The first longitudinal direction D1 approximately matches the flow direction of the airflow AF in the gas flow passageway 111. Therefore, the contact area between a windward end 121 of the heat pipe 120 facing the inlet end 112 and the airflow AF can be reduced. Thus a flow resistance to the airflow caused by the heat pipe 120 can be reduced. A flow amount is thereby increased. The efficiency of heat dissipation is improved by way of heat transfer. Moreover, the amount of heat accumulated in a wake area of a rear end 122 of the heat pipe 120 can further be reduced, so as to enhance the efficiency of heat dissipation of the heat dissipation fins 110. In addition, since the contact length between the airflow AF and the first longitudinal direction D1 of the heat pipe 120 becomes longer (the contact area becomes larger), the temperature uniformity of the heat dissipation fins 110 in the direction of the airflow AF can be improved. That is, the temperature difference of the heat dissipation fins 110 from a side adjacent to the inlet end 112 to a side adjacent to the outlet end 113 can become smaller. As such, the efficiency of heat dissipation thereof can be enhanced. In addition, compared with the circular heat pipe utilized in the prior art, under the condition of the same size of the heat dissipation fins and the same spacing of the heat pipes, since the cross section of the heat pipe 120 of the embodiment perpendicular to the extension direction D3 is in an oblate shape, more heat pipes 120 can be disposed. The heat transfer amount can be thereby increased.

In the invention, the cross section of each of the heat pipes 120 perpendicular to the extension direction D3 is not limited to an oval. Other embodiments are described below, but are not intended to limit the invention.

FIG. 4 is a schematic cross-sectional view of a heat dissipation module of another embodiment of the invention, perpendicular to an extension direction of heat pipes. Please refer to FIG. 4. The structures and advantages of a heat dissipation module 100a of the embodiment and the heat dissipation module 100 are similar. The following only describes the differences between the structures. A cross section of a heat pipe 120a of the embodiment perpendicular to the extension direction D3 has a first side 123, a second side 124, a third side 125, and a fourth side 126. The first side 123 is opposite to the second side 124 and parallel to the first longitudinal direction D1. The third side 125 and the fourth side 126 are connected between the first side 123 and the second side 124 and are opposite to each other. The third side 125 is a curved surface convex toward the inlet end 112 of the gas flow passageway. The fourth side 126 is a curved surface convex toward the outlet end 113 of the gas flow passageway. That is, the third side 125 is the windward end thereof, and the fourth side 126 is the rear end thereof.

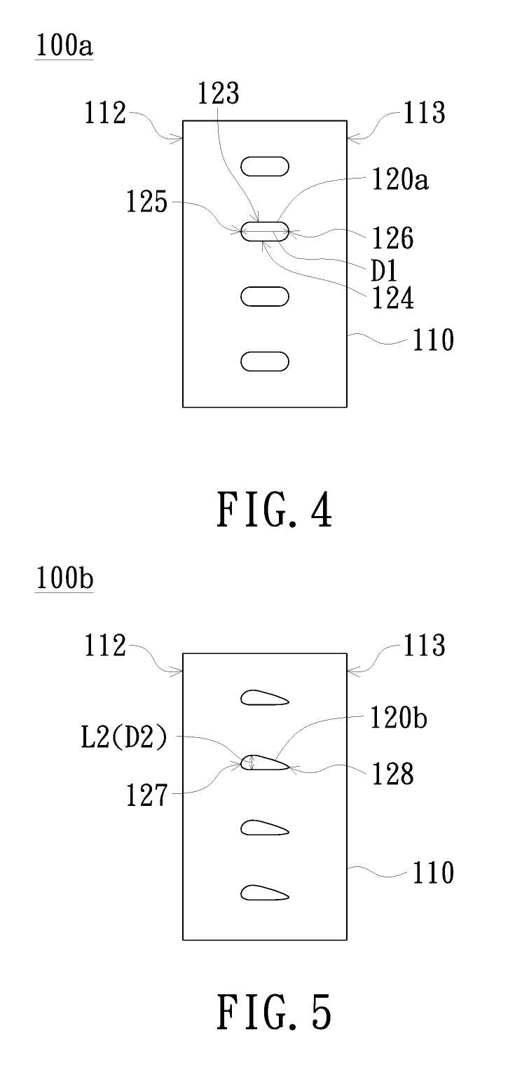

FIG. 5 is a schematic cross-sectional view of a heat dissipation module of another embodiment of the invention, perpendicular to an extension direction of heat pipes. Please refer to FIG. 5. The structures and advantages of a heat dissipation module 100b of the embodiment and the heat dissipation module 100 are similar. The following only describes the differences between the structures. A cross section of a heat pipe 120b of the embodiment perpendicular to the extension direction is, for example, in the shape of an airfoil. Specifically, the cross section of the heat pipe 120b has a first corner end 127 and a second corner end 128. The corner end may be a curved surface, a spherical surface, or an angle formed by two planes and the angle is an acute angle, but the invention is not limited thereto. The first corner end 127 faces the inlet end 112 of the gas flow passageway. The second corner end 128 faces the outlet end 113 of the gas flow passageway. That is, the first corner end 127 is the windward end thereof, and the second corner end 128 is the rear end thereof. In addition, the second corner end 128 is more pointed than the first corner end 127. For example, the length in the second longitudinal direction D2 of the heat pipe 120b gradually becomes greater and then gradually becomes less from the first corner end 127 toward the second corner end 128. The maximum length L2 of the second longitudinal direction D2 is adjacent to the first corner end 127. In such a structural design, the airflow is not separated when flowing therethrough. A wake area of the heat pipe 120b at the second corner end 128 can be eliminated. The heat transfer performance is greatly enhanced.

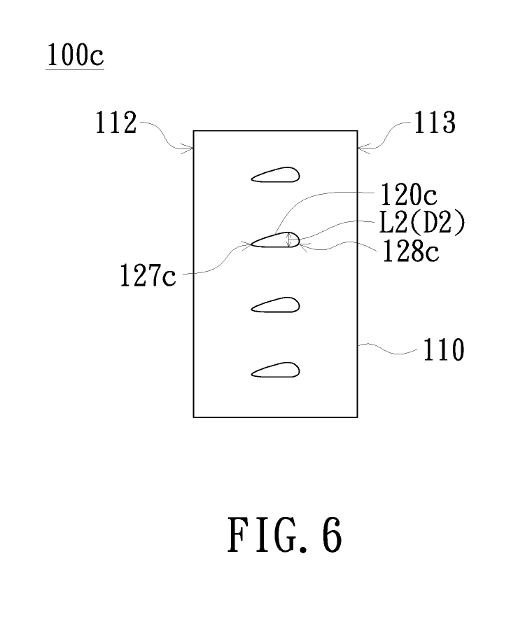

FIG. 6 is a schematic cross-sectional view of a heat dissipation module of another embodiment of the invention, perpendicular to an extension direction of heat pipes. Please refer to FIG. 6. The structures and advantages of a heat dissipation module 100c of the embodiment and the heat dissipation module 100b are similar. The following only describes the differences between the structures. A cross section of a heat pipe 120c of the embodiment perpendicular to the extension direction is, for example, in the shape of an airfoil. Specifically, the cross section has a first corner end 127c and a second corner end 128c. The first corner end 127c faces the inlet end 112 of the gas flow passageway. The second corner end 128c faces the outlet end 113 of the gas flow passageway. That is, the first corner end 127c is the windward end thereof, and the second corner end 128c is the rear end thereof. In addition, the first corner end 127c is more pointed than the second corner end 128c. The length in the second longitudinal direction D2 of the heat pipe 120c gradually becomes greater and then gradually becomes less from the first corner end 127c toward the second corner end 128c. The maximum length L2 in the second longitudinal direction D2 is adjacent to the second corner end 128c. Compared with the heat dissipation module 100b, the windward end (the first corner end 127c) of the heat pipe 120c of the embodiment is more pointed. Therefore, the flow resistance to the airflow caused by the heat pipe 120c can be reduced, so as to further increase the flow amount and to increase the heat transfer amount.

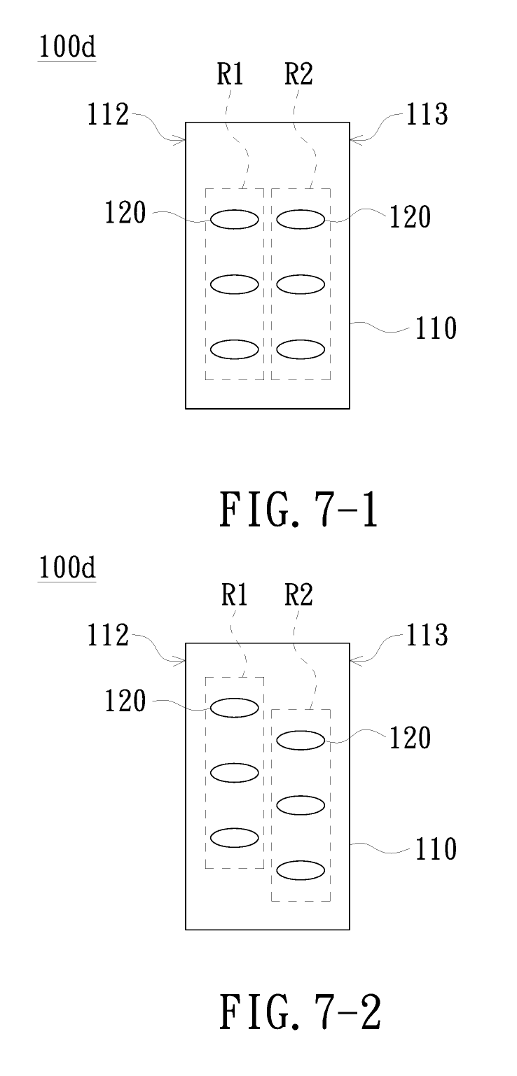

FIG. 7-1 is a schematic cross-sectional view of a heat dissipation module of another embodiment of the invention, perpendicular to an extension direction of heat pipes. Please refer to FIG. 7-1. The structures and advantages of a heat dissipation module 100d of the embodiment and the heat dissipation module 100 are similar. The following only describes the differences between the structures. In the embodiment, the heat pipes 120 are arranged in a first row R1 and a second row R2. The first row R1 is located between the inlet end 112 of the gas flow passageway and the second row R2. The heat pipes 120 of the first row R1 are arranged in parallel with the heat pipes 120 of the second row R2. In such a way of disposition, under the condition in which the spacing between the heat pipes 120 is not shortened, the number of the heat pipes 120 can be increased. The heat transfer amount can be thereby increased. The heat pipes 120a, 120b and 120c in the heat dissipation modules 100a, 100b and 100c may also be arranged in two rows.

FIG. 7-2 is a schematic cross-sectional view of a heat dissipation module of another embodiment of the invention, perpendicular to an extension direction of heat pipes. Please refer to FIG. 7-2. The structures and advantages of the heat dissipation module 100d of the embodiment and the heat dissipation module 100 are similar. The following only describes the differences between the structures. In the embodiment, the heat pipes 120 are arranged in a first row R1 and a second row R2. The first row R1 is located between the inlet end 112 of the gas flow passageway and the second row R2. The heat pipes 120 of the first row R1 are alternately arranged with the heat pipes 120 of the second row R2. In such a way of disposition, under the condition in which the spacing between the heat pipes 120 is not shortened, the number of the heat pipes 120 can be increased. The heat transfer amount can be thereby increased. The heat pipes 120a, 120b and 120c in the heat dissipation modules 100a, 100b and 100c may also be arranged in two rows.

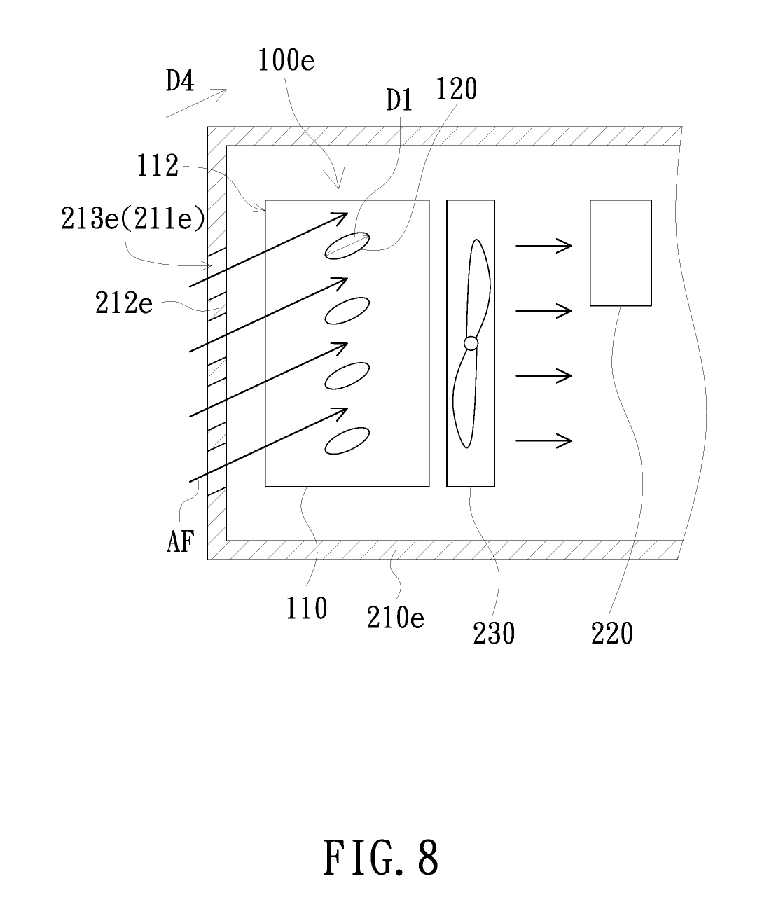

The first longitudinal direction D1 of the heat pipes 120, 120a, 120b and 120c of each of the embodiments of the invention can be adjusted according to the direction of the airflow AF, and is not limited to being perpendicular to the inlet end 112 of the gas flow passageway. Taking FIG. 8 as an example, in order to prevent the user from looking directly at the internal elements of a housing 210e of the electronic product via an air inlet 211e or to prevent a foreign matter from entering the interior of the housing 210e via the air inlet 211e, and to avoid the leakage of a light beam inside the housing 210e to interfere with a user's viewing of an image, a grid direction of a grid structure 212e is adjusted. As such, the diversion direction D4 of an air intake passageway 213e is changed, such that a direction of the airflow AF flowing into the housing 210e is not perpendicular to the inlet end 112 of the gas flow passageway. Therefore, the first longitudinal direction D1 of the heat pipe 120 of a heat dissipation module 100e also matches the direction of the airflow AF and is not perpendicular to the inlet end 112 of the gas flow passageway, so as to reduce the flow resistance to the airflow AF caused by the heat pipe 120. In addition, in FIG. 8, the fan 230 is, for example, disposed between the heat dissipation module 100e and the heat source 220. However, the fan 230 may also be disposed between the air inlet 211e and the heat dissipation module 100e, or at a side of the heat source 220 away from the heat dissipation module 100e.

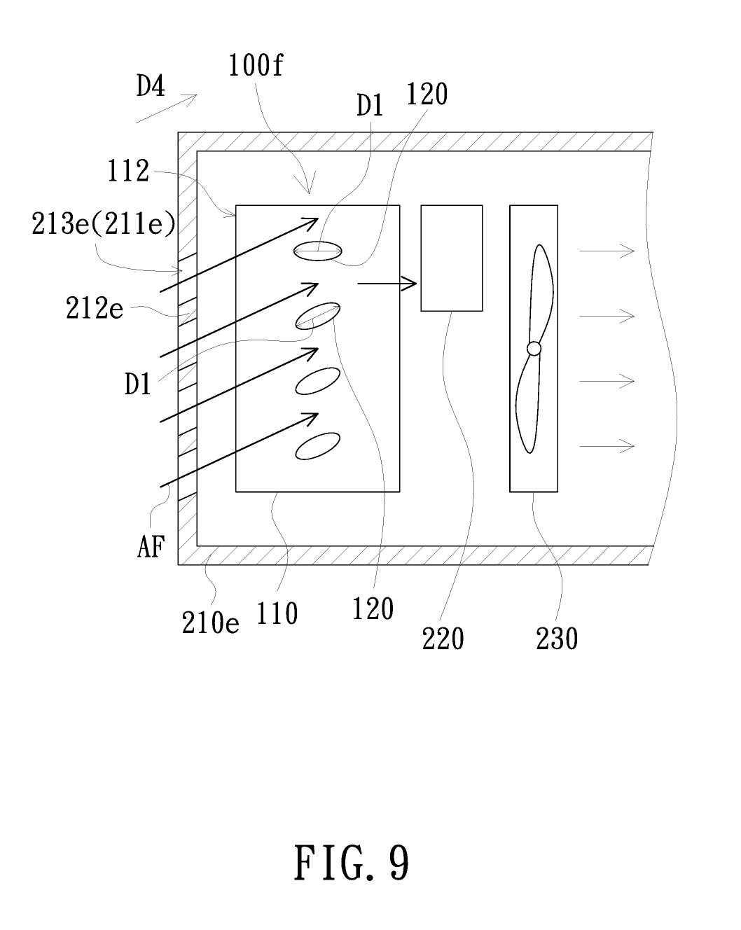

FIG. 9 is a schematic view of a heat dissipation module applied to an electronic product in accordance with another embodiment of the invention. Please refer to FIG. 9, which is similar to FIG. 8. The main difference is that in a heat dissipation module 100f of FIG. 9, the first longitudinal direction D1 of a portion of the heat pipes (for example, the topmost heat pipe 120) is perpendicular to the inlet end 112 of the gas flow passageway, but the number of the heat pipe is not limited. The first longitudinal direction D1 of the other portion of the heat pipes (for example, the other heat pipes 120) is not perpendicular to the inlet end 112 of the gas flow passageway. But the first longitudinal direction D1 of the other portion of the heat pipes (for example, the other heat pipes 120) is parallel to the flow direction of the airflow AF. As such, although a position of the heat source 220 is not in the direction of the airflow AF entering from the inlet end 112, the direction of the airflow AF can further be guided by the topmost heat pipe 120, so that the airflow AF flows through the heat source 220. In addition, in FIG. 9, the fan 230 is, for example, disposed at a side of the heat source 220 away from the heat dissipation module 100f. However, the fan 230 may also be disposed between the heat dissipation module 100f and the heat source 220, or between the air inlet 211e and the heat dissipation module 100f.

In the heat dissipation module of the embodiment of the invention, the maximum length L1 in the first longitudinal direction is greater than the maximum length L2 in the second longitudinal direction, in the cross section of the heat pipe perpendicular to the extension direction D3. When applied to a projector or other electronic device, the airflow can be configured to flow through the heat pipe along the first longitudinal direction. In this way, the flow resistance to the airflow caused by the heat pipe can be reduced. The flow amount of the airflow passing through the heat dissipation fins can be increased. The temperature uniformity of the heat dissipation fins in a direction parallel to the direction of the airflow, and air-side heat conductivity can further be enhanced. Therefore, the efficiency of heat dissipation can be enhanced.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “The invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims. Furthermore, the terms such as the first longitudinal direction, the second longitudinal direction, the first side, the second side, the third side, the fourth side, the first corner end, the second corner end, the first row, and the second row are only used for distinguishing various elements and do not limit the number of the elements.

What is claimed is:

1. A heat dissipation module, comprising:
a plurality of heat dissipation fins, wherein the heat dissipation fins are spaced apart from each other and disposed side by side, a gas flow passageway is formed between two adjacent heat dissipation fins, the gas flow passageway has an inlet end and an outlet end, and the outlet end is opposite to the inlet end; and
a plurality of heat pipes, wherein each of the heat pipes is threaded through the heat dissipation fins along an extension direction, the heat pipes are spaced apart from each other, a maximum length in a first longitudinal direction of each of the heat pipes is L1 and a maximum length in a second longitudinal direction of each of the heat pipes is L2 in a cross section of each of the heat pipes perpendicular to the extension direction, the first longitudinal direction is from the inlet end toward the outlet end, the second longitudinal direction is perpendicular to the first longitudinal direction, and L1>L2.

2. The heat dissipation module according to claim 1, wherein 1>L2/L1>0.05.

3. The heat dissipation module according to claim 1, wherein the cross section is oval.

4. The heat dissipation module according to claim 1, wherein the cross section has a first side, a second side, a third side and a fourth side, the first side is opposite to the second side and parallel to the first longitudinal direction, the third side and the fourth side are connected between the first side and the second side and opposite to each other, the third side is a curved surface convex toward the inlet end, and the fourth side is a curved surface convex toward the outlet end.

5. The heat dissipation module according to claim 1, wherein the cross section has a first corner end and a second corner end, the first corner end faces the inlet end, the second corner end faces the outlet end, a length in the second longitudinal direction gradually becomes greater and then gradually becomes less from the first corner end toward the second corner end, and a maximum length in the second longitudinal direction is adjacent to the first corner end.

6. The heat dissipation module according to claim 1, wherein the cross section has a first corner end and a second corner end, the first corner end faces the inlet end, the second corner end faces the outlet end, a length in the second longitudinal direction gradually becomes greater and then gradually becomes less from the first corner end toward the second corner end, and a maximum length in the second longitudinal direction is adjacent to the second corner end.

7. The heat dissipation module according to claim 1, wherein the first longitudinal direction of the heat pipes is perpendicular to the inlet end.

8. The heat dissipation module according to claim 1, wherein the first longitudinal direction of the heat pipes is not perpendicular to the inlet end.

9. The heat dissipation module according to claim 1, wherein the first longitudinal direction of a portion of the heat pipes is perpendicular to the inlet end, and the first longitudinal direction of the other portion of the heat pipes is not perpendicular to the inlet end.

10. The heat dissipation module according to claim 1, wherein the heat pipes are arranged in a row.

11. The heat dissipation module according to claim 1, wherein the heat pipes are arranged in a first row and a second row, the first row is located between the inlet end and the second row, and the heat pipes of the first row are alternately arranged with the heat pipes of the second row.

12. A heat dissipation module, used for a projector, wherein the projector comprises a housing and a heat source, the housing has an air inlet, the heat source and the heat dissipation module are disposed in the housing, the heat dissipation module is located between the air inlet and the heat source, and the heat dissipation module comprises:
a plurality of heat dissipation fins, wherein the heat dissipation fins are spaced apart from each other and disposed side by side, a gas flow passageway is formed between two adjacent heat dissipation fins, the gas flow passageway has an inlet end and an outlet end, and the outlet end is opposite to the inlet end; and
a plurality of heat pipes, wherein each of the heat pipes is threaded through the heat dissipation fins along an extension direction, the heat pipes are spaced apart from each other, a maximum length in a first longitudinal direction of each of the heat pipes is L1 and a maximum length in a second longitudinal direction of each of the heat pipes is L2 in a cross section of each of the heat pipes perpendicular to the extension direction, the first longitudinal direction is from the inlet end toward the outlet end, the second longitudinal direction is perpendicular to the first longitudinal direction, and L1>L2.

13. The heat dissipation module according to claim 12, wherein the projector further comprises a fan, disposed between the air inlet and the heat dissipation module, between the heat dissipation module and the heat source, or at a side of the heat source away from the heat dissipation module.

14. The heat dissipation module according to claim 12, wherein the air inlet of the housing is provided with a grid structure to form a plurality of air intake passageways, and a diversion direction of the air intake passageways is parallel to the first longitudinal direction.
